(19) United States
(12) Patent Application Publication
(10) Pub. No.: US 2008/0135887 A1
(43) Pub. Date: Jun. 12, 2008

(54) FIELD EFFECT TRANSISTOR AND FABRICATION METHOD THEREOF

(75) Inventor: Tetsuo FUKUDA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/962,572

(22) Filed: Dec. 21, 2007

Related U.S. Application Data
(63) Continuation of application No. PCT/JP2005/011595, filed on Jun. 24, 2005.

(51) Int. Cl. H01L 29/04; H01L 21/336

(52) U.S. Cl. 257/255; 438/150; 438/198; 257/E29.004; 257/E21.411; 257/E21.409

(57) ABSTRACT

On a silicon wafer (1) to which carbon is intentionally added, an element separation insulation film (2) is selectively formed. A well (3) is formed in an element active region defined by the element separation insulation film (2). When the element separation insulation film (2) and the well (3) are formed, the silicon wafer (1) is appropriately heated, so that after the well (3) is formed, no precipitated oxygen exists on the well (3) and precipitated oxygen exists at a position deeper than the well (3). A silicon nitride film is formed as a gate insulation film (4) on the well (3). A silicon film is formed on the gate insulation film (4), and these are patterned to form a gate electrode (6).

### TECHNICAL FIELD

The present invention relates to a field effect transistor with improved performance thereof and a method of fabricating the same.

### BACKGROUND ART

A transistor is an important element for a semiconductor device and a performance improvement thereof directly contributes to a performance improvement of an electronic device provided with the semiconductor device.

A lot of transistors are formed on silicon wafers. Ninety percent or more of the silicon wafers are produced by processing a silicon single crystal ingot manufactured by Czochralski method. When a semiconductor device using such a silicon wafer is fabricated, there is a possibility that heavy metals such as iron (Fe), copper (Cu), nickel (Ni) and chromium (Cr) are emitted from high-temperature materials in a heat treatment furnace, and are absorbed on a surface of the wafer or diffused inside thereof. When such a phenomenon occurs, unnecessary silicides (compounds of heavy metal and silicon) tend to be generated. Since many of such suicides are electrically active, when the silicide is generated in an operation region (channel, PN junction portion and the like) of the transistor, a leak current may be generated which causes a malfunction of the transistor.

Accordingly, a gettering technique which performs to capture heavy metal elements is applied to a bulk portion positioned at deep in the wafer (position at 10 μm or deeper from a surface, for example) and, a study for a technology to reduce the scattering of the heavy metal elements as much as possible (clean technology) at the time of fabricating the semiconductor device is in progress. Note that the heavy metal elements are also called contamination metal elements because they degrade the transistor performance.

A silicon wafer produced by using Czochralski method contains carbon impurities and oxygen impurities, if not being intentionally added, at concentrations of 10¹³ to 10¹⁵ cm⁻³, and 10¹⁷ to 10¹⁸ cm⁻³, respectively. The oxygen is present in supersaturated concentrations during a heat treatment in a fabricating process of the semiconductor device. Therefore, the subsequent heat treatment causes the clustering of oxygen with carbon as nucleus to generate a kind of crystal defects, so called precipitated oxygen. It is known that the precipitated oxygen has a characteristic to capture the heavy metal elements such as iron (Fe), copper (Cu), nickel (Ni) and chromium (Cr) which are emitted from the heat treatment furnace to a surface of the wafer. This characteristic is widely and industrially applied as a gettering technique.

To apply this technique, the oxygen concentration of a wafer, the heat treatment condition of each steps and the like are determined to control such that, for example, no precipitated oxygen is generated in a surface layer portion (region up to the depth of about 10 μm from a surface), which is very vulnerable to the leak current due to the existence of the precipitated oxygen, but in a region deeper than the surface layer portion (bulk portion), the precipitated oxygen with a density of, for example, 10⁷ cm⁻³ or more is generated. These processes utilize such a characteristic that a diffusion constant of carbon in a silicon crystal, on condition of being under 1000° C. for example, is quite small to be around one tenth of that of oxygen (non-patent document 2) so that only oxygen tends to diffuse outward from the surface layer portion.

By performing such processes, even if the heavy metal elements are emitted, the heavy metal elements are captured by the precipitated oxygen so that the operation region of the transistor positioned in the surface layer portion is protected from the contamination of the heavy metal elements.

Further, a gettering ability of the contamination elements becomes stronger as a density of precipitated oxygen increases. Therefore, conventionally, there is proposed a method to increase the density of precipitated oxygen by adding carbon intentionally to the wafer (patent documents 1 to 7). As the density of precipitated nucleus becomes large by adding carbon, the density of precipitated oxygen becomes large. However, the size of precipitates becomes small.

For example, the non-patent document 1 describes that when a heat treatment is performed to a wafer containing oxygen atoms and carbon atoms at concentrations of 0.9×10¹⁸ to 1.0×10¹⁸ cm⁻³, and 0.8×10¹⁷ to 1.2×10¹⁷ cm⁻³, respectively, at 800° C. for 20 hours followed by another heat treatment at 1100° C. for 4 hours, the precipitated oxygen having a diameter of 5 to 50 nm is formed at a density of 3×10¹² cm⁻³. On the other hand, when a similar heat treatment is performed to a wafer to which carbon is not intentionally added, the precipitated oxygen having a diameter of several hundred to several thousand nm is formed at a density of about 10⁷ to 10⁹ cm³. As above, adding carbon has a great influence on the generation of precipitated oxygen. Table 1 shows the results.

TABLE 1

| | Concentration | | Density of |
|---|---|---|---|
| | of Carbon | Diameter of | Precipitated |
| | Atoms | Precipitates | Oxygen |
| Carbon | (cm³) | (nm) | (cm³) |
| intentionally | 0.8 × 10¹⁷~1.2 × 10¹⁷ | 5~50 | 3 × 10¹² |
| added | | | |
| not | 10¹³~10¹⁵ | several 100~several | 10⁷~10⁹ |
| intentionally | | 1000 | |
| added | | | |

On the other hand, it is also confirmed that a very small precipitated oxygen having a diameter of several 10 nm has an effect to prevent dislocation movements (solution hardening) (non-patent document 1). Generally, a dislocation is generated at a portion being in contact with a boat portion which supports a backside surface of a wafer during a heat treatment. Further, since there are thermal stress and bending stress applied to various places of the wafer at the time of the heat treatment, the generated dislocation tends to move in accordance with these stresses. Since the dislocation has a characteristic to be electrically active by capturing heavy metals, when the dislocation travels from a backside surface to a front-side surface of the wafer, a leak source of the transistor is generated on the front-side surface of the wafer. Furthermore, when a lot of dislocations reach the front-side surface, the strain of front- and backside surface of the wafer becomes off-balanced, which may result in the wafer warpage. When the wafer is curved, there arises such a problem that a pattern failure or an overlay failure is caused by defocus in a lithography process, which is well known.

As described above, the dislocation movement causes various troubles. However, in a wafer to which carbon is added to generate a lot of very small precipitated oxygen, the dislocation movement is restricted by these precipitates. Such a performance to restrict the dislocation movement is very preferable for a large diameter wafer having a diameter of 300 mm or larger, and an annealed wafer and an SIMOX (Separation by IMplanted OXygen) wafer which need to go through a high-temperature heat treatment (to annealed wafer, for example, at 1200° C. for 1 hour, to SIMOX wafer, for example, at 1350° C. for 5 hours). The SIMOX wafer is a kind of SOI (Silicon On Insulator) wafer, in which a single-crystal silicon layer is remained on a surface thereof and a buried oxide film is formed by performing a heat treatment to a silicon substrate after ion-implanting oxygen therein.

Note that, in order to add carbon to the wafer, it is only needed to mix, for example, carbon monoxide (CO) gas at a predetermined flow rate with purging gas (usually, argon (Ar)) in a manufacturing furnace at the time of manufacturing a silicon single crystal ingot by Czochralski method. Therefore, there is almost no increase in cost of the wafer caused by the addition of carbon.

However, although having a quite preferable characteristic as above, the wafer with added carbon therein is lack in practicality and is not used in actual mass-produced semiconductor devices. This is because a desired electrical insulation performance of a gate insulation film can not be obtained when an MOS transistor using such a wafer is fabricated.

Patent document 1: Japanese Patent Application Laid-open No. Hei 10-303138

Patent document 2: Japanese Patent Application Laid-open No. 2000-344598

Patent document 3: Japanese Patent Application Laid-open No. 2001-274165

Patent document 4: Japanese Patent Application Laid-open No. 2001-274166

Patent document 5: Japanese Patent Application Laid-open No. Hei 04-276625

Patent document 6: Japanese Patent Application Laid-open No. 2002-57159

Patent document 7: Japanese Patent Application Laid-open No. Sho 60-094722

Non-patent document 1: K. Yasutake, M. Umeno, and H. Kawabe, Appl. Phys. Lett. 37, 789 (1980)

Non-patent document 2: H. F. Wolf, Silicon Semiconductor Data (Pergamon Press), pp. 141

Non-patent document 3: R. C. Newman and J. B. Willis, Phys. Chem. Solids 26, 373 (1965)

### SUMMARY OF THE INVENTION

According to one aspect of the present invention, there is a field effect transistor according to the present invention having a silicon substrate provided with a bulk portion containing precipitated oxygen therein and a surface layer portion positioned on the bulk portion and containing substantially no precipitated oxygen therein. Further, it is also provided with a gate insulation film including a silicon nitride film contacting with the silicon substrate and a gate electrode formed on the gate insulation film.

According to another aspect of the present invention, there is a fabrication method of a field effect transistor having the steps of: performing a heat treatment to a silicon substrate containing carbon atoms solid-solved at a concentration of 5×10¹⁵ cm⁻³ or more, thereby, inside said silicon substrate, a bulk portion containing precipitated oxygen therein, and a surface layer portion positioned on said bulk portion and containing substantially no precipitated oxygen therein are formed; forming a gate insulation film including a silicon nitride film contacting with said silicon substrate; and forming a gate electrode on said gate insulation film.

### BRIEF DESCRIPTION OF THE DRAWINGS

FIG. 1A is a sectional view showing a conventional method of fabricating a semiconductor device;

FIG. 1B is a sectional view showing the method of fabricating the semiconductor device following FIG. 1A;

FIG. 1C is a sectional view showing the method of fabricating the semiconductor device following FIG. 1B;

FIG. 2A is a view showing concentration profiles of oxygen and carbon in a state being shown in FIG. 1A;

FIG. 2B is a view showing concentration profiles of oxygen and carbon in a state being shown in FIG. 1B;

FIG. 3A is a sectional view showing a basic principle of the present invention;

FIG. 3B is a sectional view showing the basic principle of the present invention similar to FIG. 3A;

FIG. 4A is a sectional view showing a method of fabricating a semiconductor device according to an embodiment of the present invention;

FIG. 4B is a sectional view showing the method of fabricating a semiconductor device following FIG. 4A;

FIG. 4C is a sectional view showing the method of fabricating a semiconductor device following FIG. 4B;

FIG. 4D is a sectional view showing the method of fabricating a semiconductor device following FIG. 4C; and

FIG. 4E is a sectional view showing the method of fabricating a semiconductor device following FIG. 4D.

### DETAILED DESCRIPTION OF THE PREFERRED EMBODIMENTS

It is an object of the present invention to provide a field effect transistor capable of ensuring an excellent insulation performance of a gate insulation film even when a carbon-added silicon substrate is used, and a fabricating method thereof.

As a result of earnest studies to solve the above-described problems, the present inventor has found that oxygen composing a gate insulation film and carbon added to a wafer cause deterioration of the insulation performance of the gate insulation film. Conventionally, a silicon oxide (SiO₂) film or a silicon oxynitride (SiON) film is mainly used as a gate insulation film. Oxygen or water vapor reacts with silicon to generate silicate ions (SiO₄)⁴⁻, and this reaction progresses into the inside of the wafer to thereby form the silicon oxide film. Therefore, when a surface of the wafer containing carbon therein is thermally oxidized, the carbon is also taken into the silicon oxide film.

Additionally, in the silicon oxide film, oxygen combines with carbon to generate precipitated oxygen which exhibits conducting properties. As a result, an electrical insulation performance of the gate insulation film deteriorates.

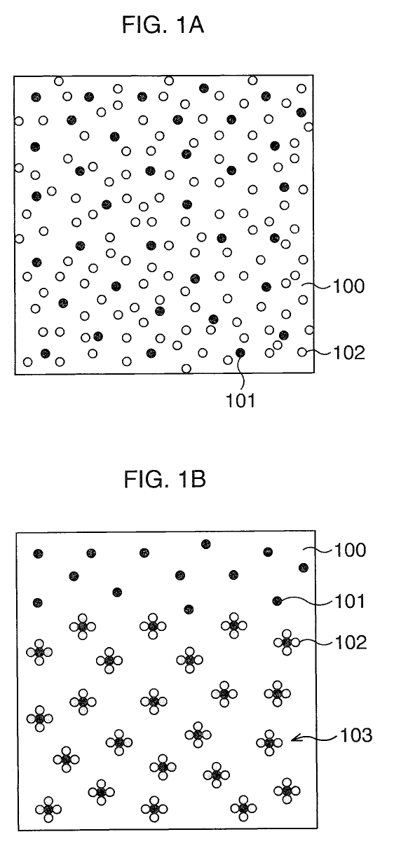

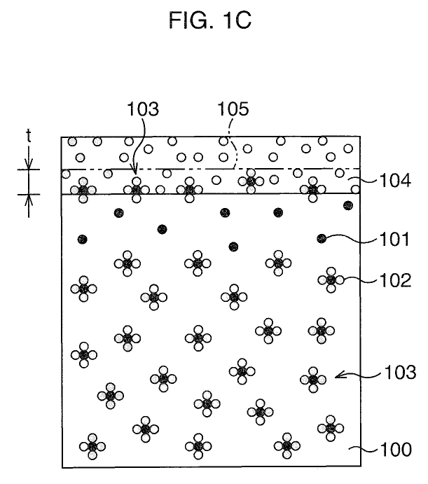

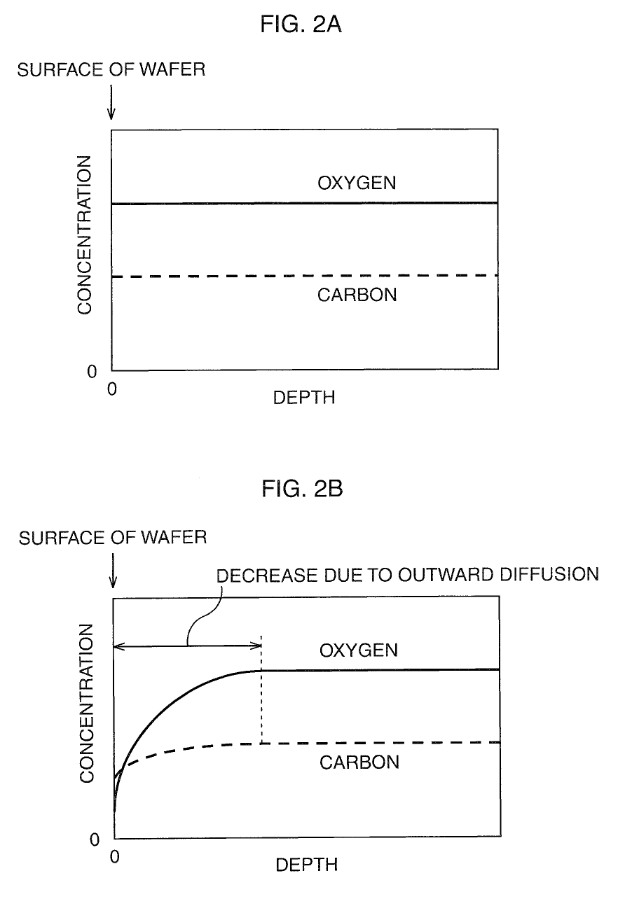

Such a phenomenon will be described with reference to attached drawings. FIGS. 1A to 1C are sectional views showing a conventional method of fabricating a semiconductor device, and FIG. 2A and FIG. 2B are views showing concentration profiles of oxygen and carbon in a state being shown in FIG. 1A and FIG. 1B, respectively.

As shown in FIG. 1A, in a wafer 100 cut out from a silicon single crystal ingot to which carbon is added, carbon 101 and oxygen 102 are distributed entirely and uniformly. Therefore, the concentrations are almost uniform at any depth, as shown in FIG. 2A. In other words, in an industrially controlled wafer, an impurity concentration in depth direction is constant. An oxygen concentration in the wafer 100 is 10¹⁷ to 10¹⁸ cm⁻³. On the other hand, a saturated concentration of carbon is about 10¹⁷ cm⁻³ even in the vicinity of melting point of the silicon, where the saturated concentration becomes the highest. Thus, there is no possibility that the concentration of added carbon exceeds that of oxygen.

When a heat treatment is performed thereafter, since a diffusion constant of carbon is about one tenth of that of oxygen (non-patent document 2), in the vicinity of surface of the wafer 100, the oxygen concentration significantly decreases due to the outward diffusion, on the other hand, the carbon concentration shows a slight decrease, as shown in FIG. 1B and FIG. 2B. The oxygen 102 remaining in the wafer 100 reacts with the carbon 101 to generate precipitated oxygen 103. The precipitated oxygen 103 has not only a gettering effect but also an effect to prevent dislocation movements. It should be noted that, although FIG. 1B is drawn such that the precipitated oxygen 103 is composed of one carbon atom (nucleus) and four oxygen atoms combined thereto, it is intended to simply explain a mechanism that carbon is used as nucleus when being precipitated, and it does not show the actual structure of the precipitated oxygen.

As shown in FIG. 1C, when a gate oxide film 104 is formed by thermal oxidation, the carbon 101 existing in a region from a surface 105 to the depth t of the wafer 100, which is a wafer before the gate oxide film 104 is formed thereon, is taken into the gate oxide film 104. The depth t corresponds to about 45% in thickness of the gate oxide film 104. Therefore, the precipitated oxygen 103 is also generated in the gate oxide film 104. Such a phenomenon occurs similarly when a silicon oxynitride film is formed by thermal oxidation.

### Basic Principle of Present Invention

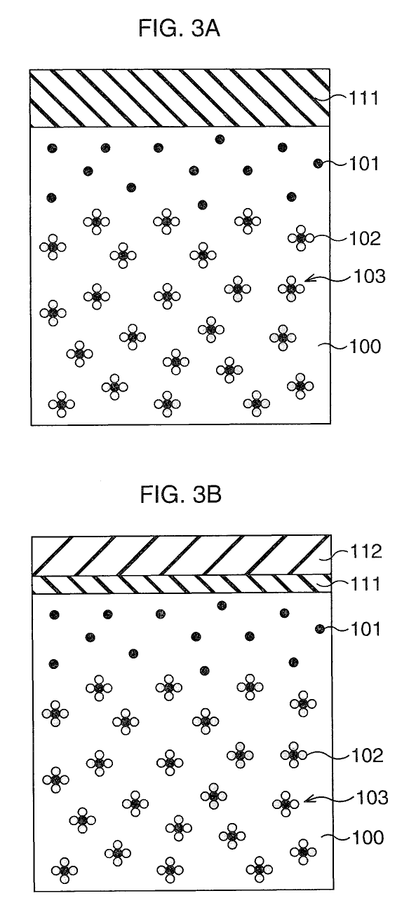

First, a basic principle of the present invention will be explained. As described above, in a conventional fabricating method, a silicon oxide film or a silicon oxynitride film is formed by thermal oxidation as a gate insulation film, which results in generating precipitated oxygen in the gate insulation film. On the contrary, in the present invention, as a gate insulation film, a silicon nitride film 111 is formed, or a silicon nitride film 111 and a high dielectric constant film (except for the silicon nitride film) 112 are sequentially formed, on a carbon-added silicon wafer (silicon substrate) 100 as shown in FIG. 3A and FIG. 3B, respectively.

When the silicon nitride film 111 is formed by a deposition method such as CVD method, there is no possibility that a surface layer portion of the silicon wafer 100 is taken into the silicon nitride film 111. On the other hand, when the silicon nitride film 111 is formed by thermal oxidation, the surface layer portion of the silicon wafer 100 is taken into the silicon nitride film 111. However, the silicon nitride film 111 contains almost no oxygen therein since oxygen is diffused outward from the surface layer portion of the wafer 100 as shown in FIG. 1B and FIG. 2B. Therefore, irrespective of a method of forming the silicon nitride film 111, it is prevented to generate precipitated oxygen in the gate insulation film. Note that carbon atoms in the silicon wafer 100 are electrically neutral, which exhibits no conducting properties (non-patent document 3).

### Embodiment of Present Invention

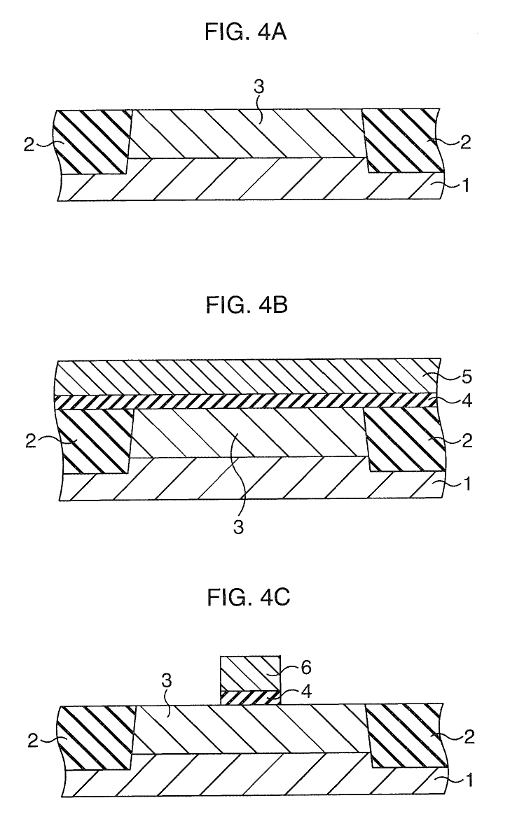

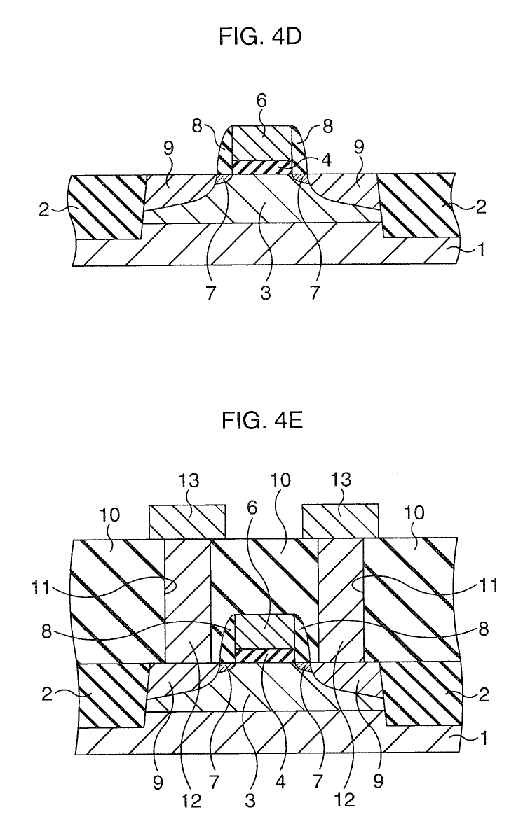

Next, an embodiment of the present invention will be described specifically with reference to the attached drawings. Here, for the sake of convenience, a cross-sectional structure of the semiconductor device will be described together with a fabricating method thereof. FIGS. 4A to 4E are sectional views showing a method of fabricating a semiconductor device according to an embodiment of the present invention in order of steps.

First, in the present embodiment, an element separation insulation film 2 is selectively formed on a silicon wafer (silicon substrate) 1 to which carbon is intentionally added as shown in FIG. 4A. Next, a well 3 is formed in an element active region defined by the element separation insulation film 2. When the element separation insulation film 2 and the well 3 are formed, the silicon wafer 1 is appropriately heated so as to obtain profiles of carbon and oxygen as shown in FIG. 1B and FIG. 2B. In other words, it should be controlled such that after the well 3 is formed, no precipitated oxygen exists on a surface layer portion up to the depth of about 10 μm from a surface of the silicon wafer 1 and precipitated oxygen exists on a bulk portion deeper than the surface layer portion. According to the study of the present inventors, it is predicable that even if a concentration of carbon atoms is 10¹⁵ cm⁻³ or more, no precipitated oxygen is generated in a region where a concentration of oxygen atoms is 5×10¹⁶ cm⁻³ or less, under the condition that a temperature of heat treatment when the semiconductor device is fabricated is 1000° C. or lower. Therefore, it is preferable to set the concentration of oxygen atoms to be 5×10¹⁶ cm⁻³ or less in the surface layer portion up to the depth of about 10 μm from a surface of the silicon wafer 1. Adjustments of temperature, time and the like to obtain such profiles can be conducted similarly to the conventional method.

Next, as shown in FIG. 4B, a gate insulation film 4 is formed on the well 3. As a gate insulation film 4, a silicon nitride (Si₃N₄) film is formed, for example. Also as a gate insulation film 4, a multilayer structure of a silicon nitride film and at least one high dielectric constant film except for the silicon nitride film can be formed. As a high dielectric constant film except for the silicon nitride film, a hafnium oxide (HfO₂) film, a zirconium oxide (ZrO₂) film, a hafnium oxynitride (HfON) film, a zirconium oxynitride (ZrON) film, a hafnium silicate (HfSiO) film, a zirconium silicate (ZrSiO) film, a hafnium silicate nitride (HfSiON) film and a zirconium silicate nitride (ZrSiON) film can be cited.

A method of forming the silicon nitride film is not particularly limited. For example, the silicon nitride film can be formed by directly nitriding a surface of the silicon wafer 1 (well 3) by plasma nitridation or thermal nitridation, and a deposition method such as CVD (Chemical Vapor Deposition) method can also be applied to form the silicon nitride film.

In the former method, the silicon nitride film is formed while consuming a surface of the silicon wafer 1 (well 3) so that carbon existing in the silicon wafer 1 (well 3) is taken into the silicon nitride film. However, since the silicon nitride film contains no oxygen therein, there is no possibility that the precipitated oxygen is generated and that the carbon has conducting properties.

Further, in the latter method, silicon (Si) and nitrogen gas (N₂) are respectively supplied from source gas, and make them react on a surface of the silicon wafer 1 (well 3) to thereby deposit the silicon nitride film, so that a surface of the silicon wafer 1 (well 3) is not consumed at all. Therefore, the silicon nitride film never takes carbon therein. Note that, since the silicon nitride film formed by CVD method contains some hydroxyl groups (—OH), if carbon is taken into the silicon nitride film, it is conceivable that oxygen and carbon composing the hydroxyl group develop a reaction to generate precipitated oxygen. However, in the present embodiment, such problems never occur since there is no possibility that carbon is taken into the silicon nitride film.

After the formation of the gate insulation film 4, a polycrystalline silicon film 5 is formed on the gate insulation film 4 as shown in FIG. 4B.

A gate electrode 6 is then formed by patterning the polycrystalline silicon film 5 and the gate insulation film 4 as shown in FIG. 4C.

After that, extension layers 7, a sidewall insulation film 8 and source/drain diffusion layers 9 are formed as shown in FIG. 4D.

Next, as shown in FIG. 4E, an interlayer insulation film 10 is formed on an entire surface, and contact holes 11 are formed therein. Contact plugs 12 are then buried in the contact holes 11. Subsequently, wirings 13 to be connected to the contact plugs 12 are formed on the interlayer insulation film 10.

After that, a multilayer wiring, a cover film and so on are formed, thereby completing the semiconductor device.

According to such an embodiment, a desired insulation performance can be obtained because the generation of precipitated oxygen in the gate insulation film 4 is prevented. In other words, even when the silicon wafer 1 to which carbon is intentionally added is used, it is possible to ensure as equivalent insulation performance of the gate insulation film 4, as in the case when a silicon wafer to which carbon is not intentionally added is used.

Therefore, it is possible not only to obtain an excellent gettering ability but also to restrict dislocation movements while ensuring a desired insulation performance.

Note that a channel region (well 3) and the source/drain diffusion layers 9 also contain carbon therein. However, since the oxygen concentration in these regions is quite low, the carbon remains electrically neutral, which will never cause Coulomb scattering of a carrier and also never be a source of a leak current.

Note that the concentration of carbon atoms and oxygen atoms in a wafer in which oxygen is not diffused outward yet is, for example, 1×10¹⁷ cm⁻³ and 1×10¹⁸ cm⁻³, respectively. Further, after the oxygen is diffused outward, it is preferable to set the concentration of carbon atoms to be not lower than 5×10¹⁵ cm⁻³ nor higher than the solubility limit. This is to ensure a sufficient gettering ability in a bulk portion and to restrict dislocation movements effectively. Furthermore, after the oxygen is diffused outward, it is preferable to set the concentration of oxygen atoms to be 5×10¹⁶ cm⁻³ or lower in a surface layer portion up to the depth of about 10 μm from a surface. This is to prevent the generation of precipitated oxygen in the surface layer portion during a heat treatment performed at 1000° C. or lower.

In the above-described embodiment, oxygen is diffused outward when forming the element separation insulation film 2 and the well 3. It is also possible to make oxygen in the surface layer portion diffuse outward by performing, before the formation of the element separation insulation film 2 and the well 3, a heat treatment at, for example, 1200° C. for about 1 hour in an inert gas atmosphere of argon (Ar) or the like. Such a wafer is called an annealed wafer.

Further, a surface of the silicon wafer is, for example, (100) face, (110) face or (113) face. When a surface is (110) face, it is possible to obtain a high hole mobility especially in a p-channel MOS transistor. Furthermore, when a surface is (113) face, it is possible to reduce especially a dangling bond on a surface thereof.

Further, a channel orientation is set to be, for example, either [011] direction or its crystallographically equivalent direction (<011> direction) or [001] direction or its crystallographically equivalent direction (<001> direction). Especially when the channel orientation is <001> direction, a high charge mobility can be obtained.

Further, as a wafer, other than a normal wafer cut out from a silicon single crystal ingot, for example, an epitaxial wafer, to which an epitaxial layer is provided, an SOI wafer and an SIMOX wafer can be used. For example, the SIMOX wafer can be manufactured in such a manner. First, an oxygen ion is injected into a silicon wafer having surface orientation (100) under the conditions of a dose amount of about 1.2×10¹⁸ cm⁻² and an energy of 180 keV. Subsequently, a heat treatment is performed in a mixed gas atmosphere of argon (Ar) and oxygen (O₂) at 1350° C. for 5 hours. By performing this heat treatment, a silicon oxide film is formed in a region where the injected oxygen ion existed and oxygen is diffused outward from the surface layer portion.

### INDUSTRIAL APPLICABILITY

As described in detail, according to the present invention, it is possible to prevent the generation of precipitated oxygen in a gate insulation film even when a silicon substrate contains a lot of carbon solid-solved therein, since there is provided a silicon nitride film at a portion contacting with the silicon substrate of the gate insulation film. Therefore, an excellent insulation performance of the gate insulation film can be ensured even at the time of using a silicon substrate to which carbon is intentionally added.

What is claimed is:

1. A field effect transistor comprising:
a silicon substrate provided with a bulk portion containing precipitated oxygen therein, and a surface layer portion positioned on said bulk portion and containing substantially no precipitated oxygen therein;
a gate insulation film including a silicon nitride film contacting with said silicon substrate; and
a gate electrode formed on said gate insulation film.

2. The field effect transistor according to claim 1, wherein said gate insulation film has at least one high dielectric constant film formed between said silicon nitride film and said gate electrode.

3. The field effect transistor according to claim 2, wherein said high dielectric constant film is a film selected from a group consisting of a hafnium oxide (HfO₂) film, a zirconium oxide (ZrO₂) film, a hafnium oxynitride (HfON) film, a zirconium oxynitride (ZrON) film, a hafnium silicate (HfSiO) film, a zirconium silicate (ZrSiO) film, a hafnium silicate nitride (HfSiON) film and a zirconium silicate nitride (ZrSiON) film.

4. The field effect transistor according to claim 1, wherein a surface of said silicon substrate is a face selected from a group consisting of crystallographical (100) face, (110) face and (113) face.

5. The field effect transistor according to claim 1, wherein a channel direction is crystallographical <001> direction.

6. The field effect transistor according to claim 1, wherein said silicon substrate is composed of an epitaxial wafer.

7. The field effect transistor according to claim 1, wherein said silicon substrate is composed of an SIMOX wafer.

8. The field effect transistor according to claim 1, wherein said silicon substrate is composed of an SOI wafer.

9. The field effect transistor according to claim 1, wherein said surface layer portion is a region up to a depth of 10 μm from a surface of said silicon substrate.

10. A fabrication method of a field effect transistor comprising the steps of:
performing a heat treatment to a silicon substrate containing carbon atoms solid-solved at a concentration of 5×10¹⁵ cm⁻³ or more, thereby, inside said silicon substrate, a bulk portion containing precipitated oxygen therein, and a surface layer portion positioned on said bulk portion and containing substantially no precipitated oxygen therein are formed;
forming a gate insulation film including a silicon nitride film contacting with said silicon substrate; and
forming a gate electrode on said gate insulation film.

11. The fabrication method of a field effect transistor according to claim 10, wherein said formation of said gate insulation film further comprises the step of forming at least one high dielectric constant film on said silicon nitride film.

12. The fabrication method of a field effect transistor according to claim 11, wherein said high dielectric constant film is a film selected from the group consisting of a hafnium oxide (HfO₂) film, a zirconium oxide (ZrO₂) film, a hafnium oxynitride (HfON) film, a zirconium oxynitride (ZrON) film, a hafnium silicate (HfSiO) film, a zirconium silicate (ZrSiO) film, a hafnium silicate nitride (HfSiON) film and a zirconium silicate nitride (ZrSiON) film.

13. The fabrication method of a field effect transistor according to claim 10, wherein a surface of said silicon substrate is a face selected from a group consisting of crystallographical (100) face, (110) face and (113) face.

14. The fabrication method of a field effect transistor according to claim 10, wherein a channel direction is crystallographical <001> direction at the time of said formation of said gate electrode.

15. The fabrication method of a field effect transistor according to claim 10, wherein said silicon substrate is composed of an epitaxial wafer.

16. The fabrication method of a field effect transistor according to claim 10, wherein said silicon substrate is composed of an SIMOX wafer.

17. The fabrication method of a field effect transistor according to claim 10, wherein said silicon substrate is composed of an SOI wafer.

18. The fabrication method of a field effect transistor according to claim 10, wherein said surface layer portion is a region up to a depth of 10 μm from a surface of said silicon substrate.

19. The fabrication method of a field effect transistor according to claim 10, wherein said heat treatment is performed at 1100° C. or higher in an inert gas atmosphere.

20. The fabrication method of a field effect transistor according to claim 10, wherein a concentration of oxygen atoms in said surface layer portion is made to be 5×10¹⁶ cm⁻³ by said heat treatment.
